(19) United States
(12) Patent Application Publication
(10) Pub. No.: US 2016/0288246 A1
(43) Pub. Date: Oct. 6, 2016

(54) ELECTRODE BONDING APPARATUS AND ELECTRODE BONDING METHOD

(71) Applicant: TOSHIBA MITSUBISHI-ELECTRIC INDUSTRIAL SYSTEMS CORPORATION, Chuo-ku, Tokyo (JP)

(72) Inventors: Akihiro ICHINOSE, Tokyo (JP); Yoshihito YAMADA, Tokyo (JP); Tomoyuki NISHINAKA, Tokyo (JP); Akio YOSHIDA, Tokyo (JP)

(73) Assignee: TOSHIBA MITSUBISHI-ELECTRIC INDUSTRIAL SYSTEMS CORPORATION, Chuo-ku, Tokyo (JP)

(21) Appl. No.: 15/035,166

(22) PCT Filed: Nov. 6, 2013
(86) PCT No.: PCT/JP2013/079985

§ 371 Date: May 6, 2016

(51) Int. Cl. B23K 20/10; H01L 23/00; H01L 31/02; B23K 20/00; H01L 31/18

(52) U.S. Cl. CPC B23K 20/106; B23K 20/002; H01L 31/18; H01L 31/02008; H01L 24/74; B23K 2201/40

(57) ABSTRACT

The present invention has an object to provide an electrode bonding apparatus that performs ultrasonic vibration bonding on points of an electrode and is capable of reducing variations in a peel force among the points even when the electrode is bonded onto the substrate at a lower peel force. According to the present invention, a collecting electrode (20A, 20B) is disposed along a side (L1, L2) of a glass substrate (1) on a solar cell (ST1). Then, the glass substrate is pressed along the side in a region of the glass substrate between the side and an arrangement position of the collecting electrode. During application of the pressure, the ultrasonic vibration bonding is performed on the collecting electrode using an ultrasonic vibration tool (14).

### TECHNICAL FIELD

The present invention relates to a method for manufacturing a solar cell, and more specifically to bonding a component of the solar cell onto a substrate, using an ultrasonic vibration bonding method.

### BACKGROUND ART

Thin-film solar cells each formed with a power generation layer and an electrode layer on a glass substrate have conventionally been used as solar cells. Typically, each of the thin-film solar cells includes solar cells connected in series.

Furthermore, in the structures of the thin-film solar cells, electricity generated by each of the solar cells is collected by a collecting electrode (bus bar) formed in the vicinity of both sides of the glass substrate. Then, the electricity collected by the collecting electrode is derived from a lead (leader line). In other words, the lead is connected to the collecting electrode, and also to a terminal of a terminal box. The connection configuration allows the lead to derive the electricity collected by the collecting electrode to the terminal box.

Here, the collecting electrode is electrically connected to the electrode layer formed on the glass substrate in the solar cell, and the lead is not directly connected to the solar cell (specifically, the lead is electrically connected to the solar cell through the collecting electrode, but the solar cell is insulated from the lead).

The conventional techniques related to the present invention (specifically, the conventional techniques for connecting a collecting electrode or others to a substrate, using ultrasonic vibration bonding) have already existed (Patent Documents 1, 2, 3, 4, and 5).

### PRIOR-ART DOCUMENTS

### Patent Documents

Patent Document 1: International Publication WO2010/150350

Patent Document 2: Japanese Unexamined Patent Application Publication No. 2011-9261

Patent Document 3: Japanese Unexamined Patent Application Publication No. 2011-9262

Patent Document 4: Japanese Unexamined Patent Application Publication No. 2012-4280

Patent Document 5: Japanese Unexamined Patent Application Publication No. 2012-4289

### SUMMARY OF INVENTION

### Problems to be Solved by the Invention

Solar cells (solar-cell laminated films) are formed on substrates, and strip-shaped collecting electrodes are disposed on the solar cells. The ultrasonic vibration bonding is performed on the collecting electrodes. Accordingly, the electrode layer included in each of the solar cells is electrically connected to the collecting electrode, and the collecting electrode is bonded onto the substrate.

In the ultrasonic vibration bonding, ultrasonic vibration tools abut on the collecting electrodes, and apply pressure thereto. During application of the pressure, the ultrasonic vibration tools are ultrasonically vibrated in a horizontal direction. In recent years, it has been desired to bond the collecting electrodes onto the substrates at lower peel strength (bonding strength). The reason is as follows.

To increase the peel strength (bonding strength) of the collecting electrodes with respect to the substrates, the ultrasonic vibration tools are strongly pressed against the collecting electrodes. Then, the solar cells under the collecting electrodes are damaged, and the damaged solar cells do not generate electricity. Thus, it is desired to bond the collecting electrodes onto the substrates at lower peel strength (bonding strength) to prevent the solar cells from being damaged while the collecting electrodes are continuously bonded (fixed) onto the substrates. Even when the peel strength of the collecting electrodes is reduced, the collecting electrodes need to be fixed to the substrates on which the solar cells are formed.

Furthermore, when the strip-shaped collecting electrodes are bonded onto the substrates, the ultrasonic vibration bonding is performed on points (hereinafter referred to as process execution points) of the collecting electrodes along the strips. Here, it is not desired that the peel strengths (bonding strengths) of a collecting electrode greatly vary among the process execution points on the collecting electrode. This is because when the collecting electrodes are bonded onto the substrates at lower peel strength (bonding strength) and variations in the peel strength (bonding strength) are wide, at some of the process execution points, the collecting electrodes cannot be bonded onto the substrates at all, and the solar cells are damaged due to application of extremely high pressure to the collecting electrodes.

An object of the present invention is to provide an electrode bonding apparatus and an electrode bonding method that are capable of reducing variations in the peel force among points of a collecting electrode, even when the collecting electrode is bonded onto a substrate at a lower peel force by performing the ultrasonic vibration bonding on points of the collecting electrode.

### Means to Solve the Problems

In order to achieve the object, the electrode bonding apparatus according to the present invention is an electrode bonding apparatus that bonds an electrode onto a substrate on which a solar cell is formed, along a side of the substrate, the substrate being rectangular, the electrode bonding apparatus including: a table on which the substrate is mounted; an ultrasonic vibration tool that performs ultrasonic vibration bonding on the electrode disposed along the side, on the solar cell; and two pressure parts that press the substrate, the pressure parts being vertically movable, wherein the substrate has a first side, and a second side facing the first side, one of the pressure parts presses the substrate along the first side, in a first predetermined region of the substrate between the first side and an arrangement position of the electrode, and the other of the pressure parts presses the substrate along the second side, in a second predetermined region of the substrate between the second side and an arrangement position of the electrode.

Furthermore, the electrode bonding method according to the present invention is an electrode bonding method including: (A) mounting, on a table (11), a substrate (1) on which a solar cell (ST1) is formed, the substrate being rectangular; (B) disposing an electrode (20A, 20B) along a side (L1, L2) of the substrate, on the solar cell; (C) pressing the substrate along the side, in a region of the substrate between the side and an arrangement position of the electrode; and (D) bonding the electrode on the substrate by performing ultrasonic vibration bonding on the substrate during the step (C).

### Effects of the Invention

According to the present invention, the following bonding is performed on an electrode disposed along a side of a substrate on a solar cell. Specifically, the substrate is pressed along a side in a region of the substrate between the side and an arrangement point of an electrode, that is, a region of the substrate having a width from a point of the side to the arrangement position of the electrode. During application of the pressure, the ultrasonic vibration bonding is performed on the electrode to bond the electrode onto the substrate.

Even when the electrode is bonded onto the substrate 1 at a lower peel strength (bonding strength), variations in the peel strength (bonding strength) among points of the electrode can be reduced.

The objects, features, aspects and advantages of the present invention will become more apparent from the following detailed description and the accompanying drawings of the present invention.

### BRIEF DESCRIPTION OF DRAWINGS

FIG. 1 is an oblique perspective view of a glass substrate 1 on which a solar cell ST1 is formed.

FIG. 2 is an oblique perspective view of a main structure of an electrode bonding apparatus 100.

FIG. 3 is an enlarged cross-sectional view of the main structure of the electrode bonding apparatus 100.

FIG. 4 is an oblique perspective view illustrating the glass substrate 1 to be fixed and pressed by substrate fixing parts 12.

FIG. 5 is an enlarged cross-sectional view illustrating the glass substrate 1 to be fixed and pressed by the substrate fixing part 12.

FIG. 6 is an oblique perspective view illustrating collecting electrodes 20A and 20B disposed on the solar cell ST1.

FIG. 7 is an enlarged cross-sectional view illustrating the collecting electrodes 20A and 20B that are disposed on the solar cell ST1.

FIG. 8 is an enlarged cross-sectional view illustrating that an ultrasonic vibration tool 14 performs ultrasonic vibration bonding on the collecting electrodes 20A and 20B.

FIG. 9 is an oblique perspective view illustrating the collecting electrodes 20A and 20B on which the ultrasonic vibration bonding has been performed.

FIG. 10 is experimental data exhibiting the advantages of the present invention.

### DESCRIPTION OF EMBODIMENTS

The present invention employs the ultrasonic vibration bonding method (ultrasonic vibration bonding) in bonding a collecting electrode to be disposed on a solar cell. The ultrasonic vibration bonding method is a technique (process) for bonding an object (collecting electrode) onto a to-be-bonded object (solar cell substrate) by horizontally applying ultrasonic vibrations to the object while vertically applying pressure thereto. The following will specifically describe the present invention based on the drawings depicting the embodiments of the present invention.

### Embodiment

A substrate 1 (hereinafter “glass substrate 1”) that is transparent and rectangular is first prepared. Then, each of a surface electrode layer, a power generation layer, and a back electrode layer is formed onto a predetermined pattern on a first principal surface of the glass substrate 1. These processes produce a fundamental structure of a thin-film solar cell. An insulating protective film may be laminated on the first principal surface to cover all the surface electrode layer, the power generation layer, and the back electrode layer. The following description does not include the protective film for the sake of simplification.

The entire structure formed by laminating in order the surface electrode layer, the power generation layer, and the back electrode layer on the first principal surface of the glass substrate 1 will be hereinafter referred to as a solar-cell laminated film ST1 or a solar cell ST1.

The surface electrode layer, the power generation layer, and the back electrode layer are laminated in order, and each of the surface electrode layer and the back electrode layer is electrically connected to the power generation layer. Furthermore, the glass substrate 1 is, for example, a thin-film substrate with a thickness of approximately less than or equal to several millimeters. Furthermore, the surface electrode layer includes a transparent conductive film, and can be made from, for example, ZnO, ITO, or SnO₂. Furthermore, the surface electrode layer has, for example, a thickness of approximately several tens of nanometers.

Furthermore, the power generation layer is a photoelectric conversion layer that can convert incident light into electricity. The power generation layer is a thin layer having a thickness of approximately several micrometers (for example, 3 μm). Furthermore, the power generation layer, for example, contains silicon. Furthermore, the back electrode layer can be made from, for example, a conductive film containing silver. Furthermore, the back electrode layer has, for example, a thickness of approximately several tens of nanometers.

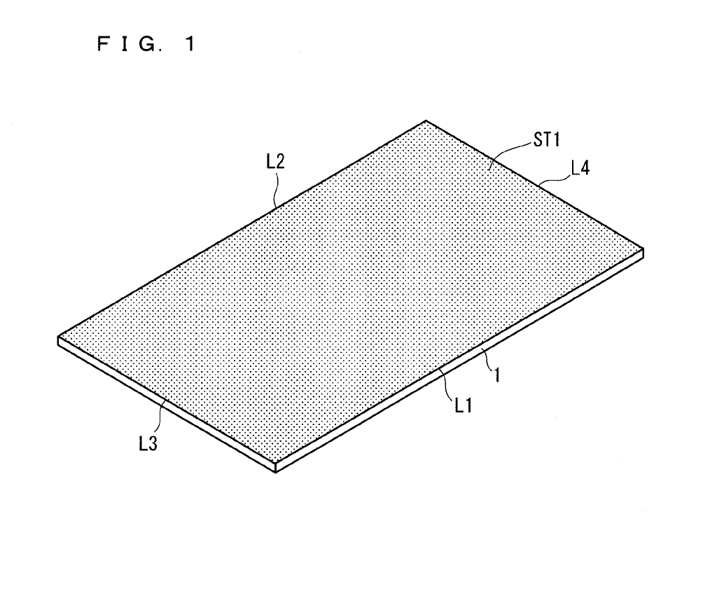

FIG. 1 is an oblique perspective view of the solar-cell laminated film ST1 formed on the first principal surface of the rectangle glass substrate 1. The solar-cell laminated film ST1 is shaded in FIG. 1. As can be viewed from FIG. 1, the first principal surface is the principal surface of the glass substrate 1 on which the solar-cell laminated film ST1 is formed. In contrast, a principal surface that faces the first principal surface and cannot be viewed from FIG. 1 is the second principal surface. On the second principal surface, the solar-cell laminated film ST1 is not formed but the glass substrate 1 is exposed.

Next, the following names are defined to simplify the description hereinafter.

The glass substrate 1 is rectangle in a planar view. Thus, the first principal surface of the glass substrate 1 has sides L1, L2, L3, and L4 as illustrated in FIG. 1. The sides L1, L2, L3, and L4 are the first side L1, the second side L2, the third side L3, and the fourth side L4.

In the structure exemplified in FIG. 1, the first side L1 and the second side L2 face and are parallel to each other, and the third side L3 and the fourth side L4 face and are parallel to each other. Furthermore, the first side L1 vertically intersects the third side L3 and the fourth side L4, and the second side L2 also vertically intersects the third side L3 and the fourth side L4, in the structure exemplified in FIG. 1.

Next, a structure of an electrode bonding apparatus 100 according to the present invention will be described.

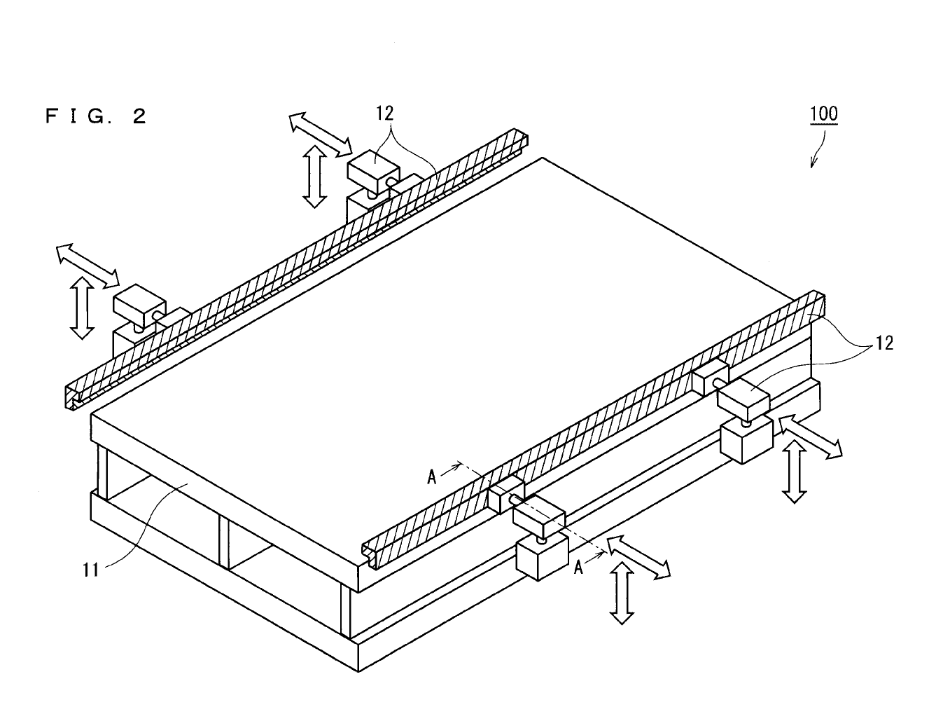

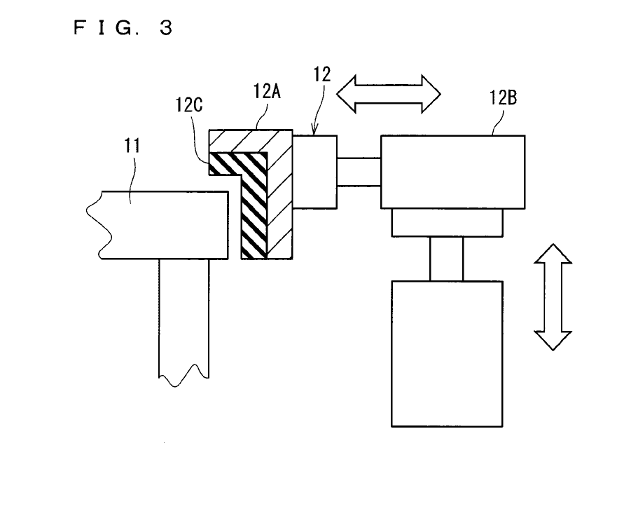

FIG. 2 is an oblique perspective view of a main structure of the electrode bonding apparatus 100. Furthermore, FIG. 3 is an enlarged cross-sectional view of the cross-sectional structure taken along the section line A-A of FIG. 2.

The electrode bonding apparatus 100 includes an ultrasonic vibration tool, a controller, a table 11, and substrate fixing parts 12. FIG. 2 omits illustrations of the ultrasonic vibration tool and the controller for the sake of simplification. As illustrated in FIG. 2, the substrate fixing parts 12 are two in number, and one of the substrate fixing parts 12 faces the other of the substrate fixing parts 12 across the table 11 that is rectangle in a planar view.

The table 11 includes a plate part, and the glass substrate 1 is mounted on the plate part. Furthermore, each of the substrate fixing part 12 includes a pressure part 12A and a driver 12B as illustrated in FIG. 3. In the example structure of FIG. 2, each of the substrate fixing parts 12 includes two of the drivers 12B.

The substrate fixing parts 12 are devices capable of fixing the glass substrate 1 to the table 11 by pressing the glass substrate 1 mounted on the table 11. One of the substrate fixing parts 12 is disposed on one of the sides of the table 11, and the other of the substrate fixing parts 12 is disposed on the other of the sides of the table 11. The substrate fixing parts 12 can vertically and horizontally move as illustrated in FIG. 3 when the drivers 12B operate.

Each of the drivers 12B includes, for example, an air cylinder, and operates vertically and horizontally in FIG. 3 as described above. Furthermore, the pressure parts 12A are fixed to portions of the drivers 12B that abut on the glass substrate 1. Thus, the pressure parts 12A move according to the operations of the drivers 12B.

The pressure parts 12A are rodlike parts that are L-shaped in a cross-sectional view (specifically, L-shaped rods) as illustrated in FIGS. 2 and 3. The sides of the pressure parts 12A that form an L-shaped right angle (90°) abut on the glass substrate 1. Furthermore, the portions of the pressure parts 12A that abut on the glass substrate 1 are elastic parts 12C. The portions of the elastic parts 12C that abut on the solar cell ST1 formed on the glass substrate 1 are softer than the portions of the elastic parts 12C that abut on the side surfaces of the glass substrate 1.

As described above, each of the substrate fixing parts 12 includes the two drivers 12B, and one of the pressure parts 12A that is fixed by the two drivers 12B.

The controller is a device that controls the operation of the substrate fixing parts 12. Specifically, the controller can variably control the pressure applied by the pressure pans 12A, and also the vertical and horizontal movement of the pressure parts 12A in FIG. 3. Furthermore, the controller can control the operation of the ultrasonic vibration tool. Specifically, the controller can variably control conditions (the number of vibrations, amplitude, and pressure) of the ultrasonic vibration bonding performed by the ultrasonic vibration tool, for example, according to an instruction from the user.

For example, the pressure applied by the pressure parts 12A against the glass substrate 1 needs to be changed, according to a material and a thickness of the collecting electrode, a material and a thickness of each film included in the solar cell ST1, and the conditions of the ultrasonic vibration bonding. Thus, the controller variably controls the pressure applied by the pressure parts 12A, according to an instruction from the user. Furthermore, upon receipt of each information item (a material and a thickness of the collecting electrode, a material and a thickness of each film included in the solar cell ST1, and the conditions of the ultrasonic vibration bonding), the controller may control the pressure parts 12A according to a predefined table and the pressure determined by the information item. The table uniquely defines the pressure for each of the information items.

Next, operations of bonding the collecting electrode onto the glass substrate 1 using the electrode bonding apparatus 100 will be described.

First, the glass substrate 1 on which the solar cell ST1 is formed is prepared. Then, the glass substrate 1 is mounted on a planar part of the table 11. The dimensions of the table 11 in a direction in which the substrate fixing parts 12 face each other (hereinafter referred to as “facing direction”) are smaller than those of the glass substrate 1 in the facing direction. Furthermore, when the glass substrate 1 is mounted on the table 11 the surface of the glass substrate 1 on which the solar cell ST1 is formed is the top surface.

Next, when the drivers 12B operate under control adjusted by the controller, the substrate fixing parts 12 horizontally move as in FIG. 3 (specifically, horizontally move toward where the glass substrate 1 is mounted). In other words, the substrate fixing parts 12 horizontally move to sandwich the glass substrate 1 from both sides.

Then, the surfaces of the pressure parts 12A facing the side surfaces of the glass substrate 1 are in contact with the side surfaces of the glass substrate 1. Then, the pressure parts 12A hold the glass substrate 1 from the both sides. Here, each of the substrate fixing parts 12 is horizontally adjusted and moves under control adjusted by the controller. The control is performed according to an instruction from the user. In other words, the position of the glass substrate 1 on the table 11 is determined according to an instruction from the user.

The adjustment herein means positioning the table 11 on which the glass substrate 1 is mounted. In other words, the adjusted movement of each of the substrate fixing parts 12 can position the glass substrate 1 on the table 11. As described above, the dimensions of the table 11 in the facing direction are smaller than those of the glass substrate 1 in the same direction. Thus, it is possible to prevent the pressure parts 12A from being in contact with the side surfaces of the table 11 in the positioning, and positioning of the glass substrate 1 using the pressure part 12A from being interfered with.

After the completion of the positioning, by operating the drivers 12B under control by the controller, the substrate fixing parts 12 move downward in FIG. 3 (specifically, in a direction where the glass substrate 1 is pressed). In other words, the substrate fixing parts 12 vertically move to press the glass substrate 1 from above.

Then, the surfaces of the pressure parts 12A facing the top surface of the glass substrate 1 are in contact with the solar cell ST1 formed on the glass substrate 1. Then, each of the pressure parts 12A presses the glass substrate 1 from above. Here, each of the substrate fixing parts 12 moves downward under control by the controller. The control is performed according to an instruction from the user. In other words, the pressure applied on the glass substrate 1 by the pressure parts 12A is determined according to an instruction from the user.

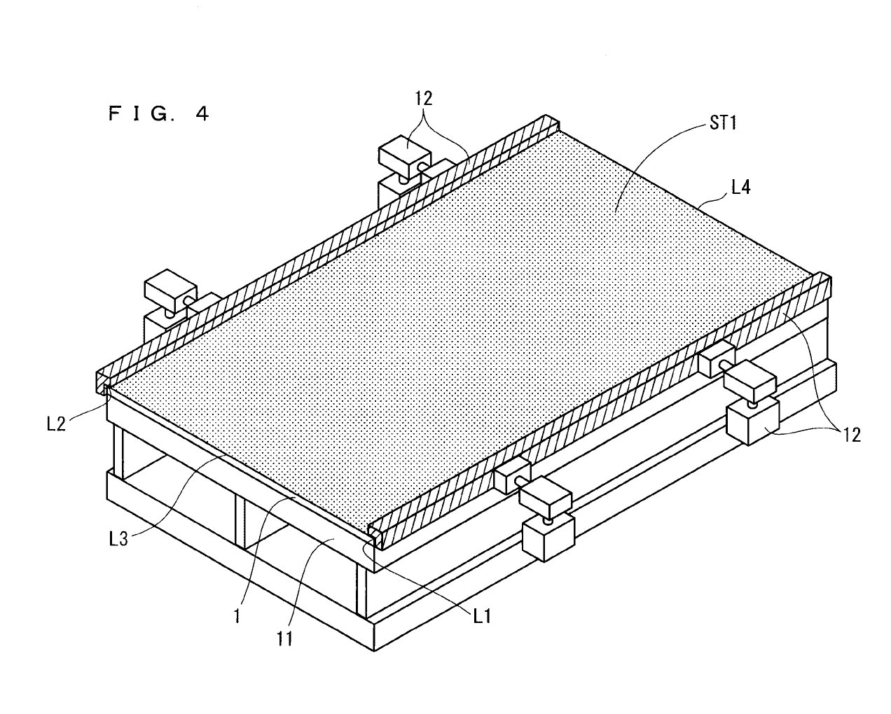

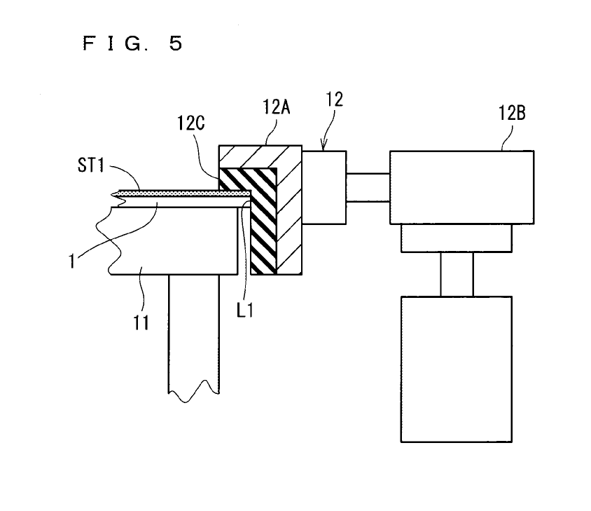

FIG. 4 is an oblique perspective view illustrating the glass substrate 1 fixed on the table 11 by the substrate fixing parts 12. Furthermore, FIG. 5 is a drawing corresponding to FIG. 3, and is an enlarged cross-sectional view illustrating the glass substrate 1 fixed on the table 11 by the substrate fixing parts 12.

As illustrated in FIGS. 4 and 5 and described in FIG. 1, the solar cell ST1 is formed, and the glass substrate 1 having the sides L1 to L4 is pressed by the pressure parts 12A. One of the pressure parts 12A that is an L-shaped rod presses the glass substrate 1 in the first side L1 along the first side L1 (specifically, along the length of the first side L1). In contrast, the other of the pressure parts 12A that is also an L-shaped rod presses the glass substrate 1 in the second side L2 along the second side L2 (specifically, along the length of the second side L2).

As illustrated in FIG. 5, the elastic part 12C included in the pressure part 12A abuts on the first side L1 (and the second side L2) of the glass substrate 1. As described above, the portions of the elastic parts 12C that abut on the solar cell ST1 formed on the glass substrate 1 are softer than those of the elastic parts 12C that abut on the side surfaces of the glass substrate 1. Thus, the portions harder in the elastic parts 12C abut on the side surfaces of the glass substrate 1 in positioning the glass substrate 1, and then horizontally hold the glass substrate 1. In contrast, the portions softer in the elastic parts 12C press the glass substrate 1 from above the glass substrate 1.

Furthermore, FIG. 5 illustrates the state where the dimensions of the table 11 in the facing direction are smaller than those of the glass substrate 1 in the same direction as described above. Furthermore, take note of the portions of the glass substrate 1 pressed by the pressure parts 12A (hereinafter referred to as pressed portions). The glass substrate 1 is sandwiched by at least lower portions of the pressed portions and the table 11. In other words, the pressure parts 12A never press only portions of the glass substrate 1 that are not mounted on the table 11 in the pressing.

Next, collecting electrodes 20A and 20B are disposed in predetermined positions on the solar cell ST1 (along the sides L1 and L2 of the glass substrate 1) in the glass substrate 1 disposed on the table 11. Here, the collecting electrodes 20A and 20B are strip-shaped conductors, and conductors containing copper, aluminum, or copper and aluminum can be used as the collecting electrodes 20A and 20B.

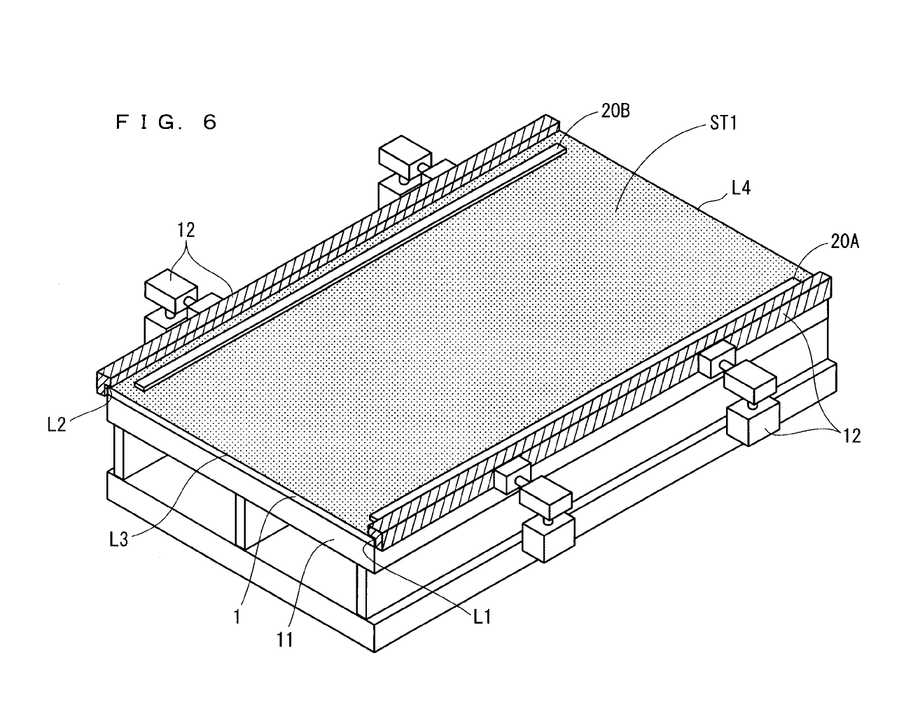

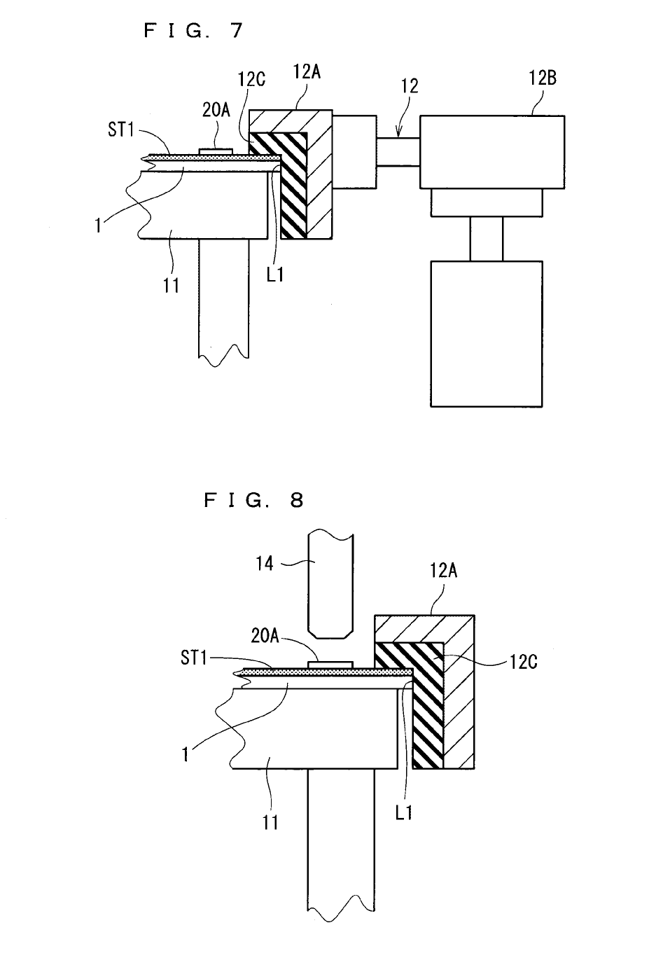

FIG. 6 is an oblique perspective view illustrating the collecting electrodes 20A and 20B disposed on the solar cell ST1 formed on the glass substrate 1. Furthermore, FIG. 7 is a drawing corresponding to FIGS. 3 and 5, and is an enlarged cross-sectional view illustrating the collecting electrodes 20A and 20B disposed on the solar cell ST1 formed on the glass substrate 1.

As illustrated in FIGS. 4 and 5, the strip-shaped collecting electrode 20A is disposed along the first side L1 away from the pressure part 12A. Similarly, the strip-shaped collecting electrode 20B is disposed along the second side L2 away from the pressure part 12A. Specifically, the collecting electrode 20A is disposed slightly distant from the first side L1, along the first side L1. Similarly, the collecting electrode 20B is disposed slightly distant from the second side L2, along the second side L2.

Thus, one of the pressure parts 12A that is an L-shaped rod presses the glass substrate 1 along the first side L1 (specifically, along the length of the first side L1), in a first region of the glass substrate 1 between the first side L1 and an arrangement position of the collecting electrode 20A. Furthermore, the other of the pressure parts 12A that is also an L-shaped rod presses the glass substrate 1 along the second side L2 (specifically, along the length of the second side L2), in a second region of the glass substrate 1 between the second side L2 and an arrangement position of the collecting electrode 20B. The width of each of the first region and the second region (specifically, each distance from the first side L1 to an arrangement position of the collecting electrode 20A and from the second side L2 to an arrangement position of the collecting electrode 20B) is, for example, approximately several millimeters.

After the glass substrate 1 is fixed by the substrate fixing parts 12, the collecting electrodes 20A and 20B are disposed on the glass substrate 1 herein. However, the collecting electrodes 20A and 20B may be disposed on the glass substrate 1 after the glass substrate 1 is mounted on the table 11, and then the glass substrate 1 may be fixed by the substrate fixing parts 12.

After the collecting electrodes 20A and 20B are disposed on the solar-cell laminated film ST1, the ultrasonic vibration bonding is performed in places on the top surfaces of the collecting electrodes 20A and 20B. Specifically, the ultrasonic vibration bonding to be described hereinafter is performed on the collecting electrodes 20A and 20B when the glass substrate 1 is fixed on the table 11 by the substrate fixing parts 12. FIG. 8 illustrates that the ultrasonic vibration bonding is performed on the top surfaces of the collecting electrodes 20A and 20B.

With reference to FIG. 8, the ultrasonic vibration tool 14 abuts on the top surfaces of the collecting electrodes 20A and 20B and applies a predetermined pressure to the abutting direction (direction toward the glass substrate 1). Then, the ultrasonic vibration tool 14 is ultrasonically vibrated in a horizontal direction (vertical to the pressure applying direction) during the application of the pressure. Accordingly, the collecting electrodes 20A and 20B can be bonded and fixed onto the solar-cell laminated film ST1. The ultrasonic vibration bonding is performed on several portions of each of the top surfaces of the collecting electrodes 20A and 20B, along the collecting electrodes 20A and 20B.

The controller determines conditions of the ultrasonic vibration bonding based on an input operation of the user, and controls the ultrasonic vibration tool 14 under the determined conditions. What is selected herein is the conditions of the ultrasonic vibration bonding under which the peel strengths (bonding strengths) of the collecting electrodes 20A and 20B have been reduced, that is, the conditions under which the collecting electrodes 20A and 20B can be bonded onto the glass substrate 1 without damaging the solar cell ST1 located below the collecting electrodes 20A and 20B (the collecting electrodes 20A and 20B can be electrically bonded onto the electrode layer without damaging the power generation layer).

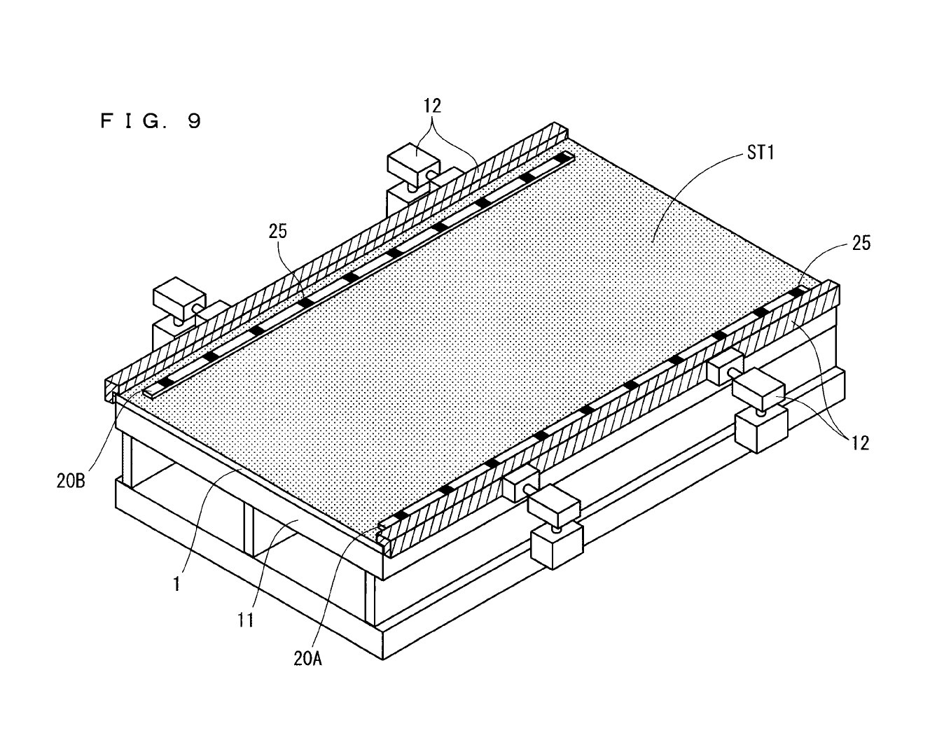

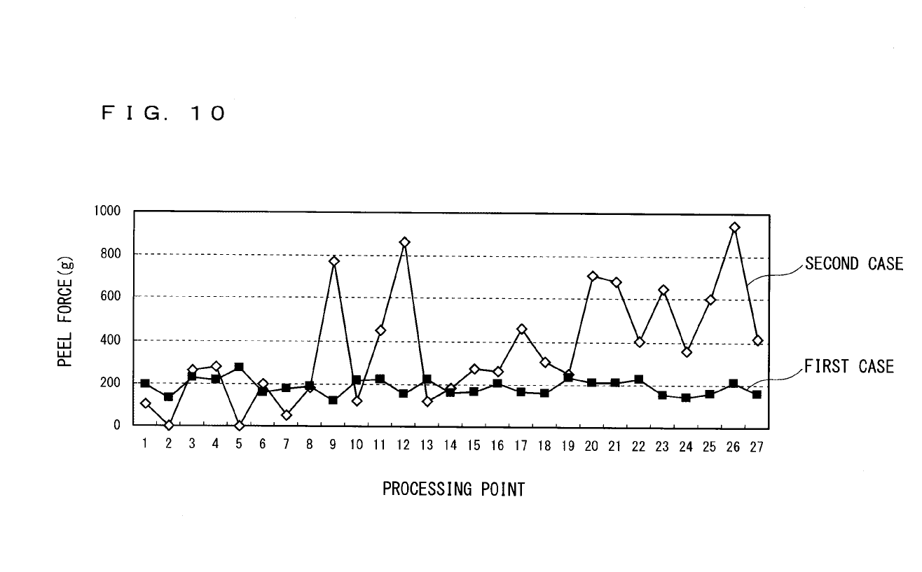

FIG. 9 is an oblique perspective view illustrating a state after the ultrasonic vibration bonding. Reference numerals 25 in FIG. 9 indicate indentations 25 formed by the ultrasonic vibration bonding. As illustrated in FIG. 9, the indentations 25 exist in places (are scattered) along the collecting electrodes 20A and 20B.

The ultrasonic vibration bonding allows the collecting electrodes 20A and 20B to be directly electrically connected (bonded) to the solar cell ST1. The electrical bonding of the collecting electrodes 20A and 20B onto the solar cell ST1 allows the collecting electrodes 20A and 20B to function as bus bar electrodes that are collecting electrodes that conduct the electricity generated by the solar cell ST1. For example, the collecting electrode 20A that is one of the collecting electrodes 20A and 20B functions as a cathode, and the collecting electrode 20B that is the other of the collecting electrodes 20A and 20B functions as an anode.

As described above, the electrode bonding apparatus 100 (electrode bonding method) according to the embodiment performs the following bonding on the collecting electrodes 20A and 20B disposed along the sides L1 and L2 on the glass substrate 1, respectively, on the solar cell ST 1. In other words, the glass substrate 1 is pressed along the side L1 in a region of the glass substrate 1 between the side L1 and an arrangement position of the collecting electrode 20A, and along the side L2 in a region of the glass substrate 1 between the side L2 and an arrangement position of the collecting electrode 20B. During application of the pressure, the ultrasonic vibration bonding is performed on the collecting electrodes 20A and 20B to bond the collecting electrodes 20A and 20B onto the glass substrate 1.

Thus, even when the collecting electrodes 20A and 20B are bonded onto the glass substrate 1 at a lower peel strength (bonding strength), variations in the peel strength among points can be reduced. FIG. 10 is experimental data exhibiting the advantages of the present invention.

The Inventors performed the ultrasonic vibration bonding on the collecting electrodes 20A and 20B by pressing and fixing the sides L1 and L2 using the substrate fixing parts 12 (a first case). Furthermore, the Inventors performed the ultrasonic vibration bonding on the collecting electrodes 20A and 20B without pressing and fixing the sides L1 and L2 using the substrate fixing parts 12 (a second case). In the first and second cases, the ultrasonic vibration bonding was performed in places on the strip-shaped collecting electrodes 20A and 20B several times, along a direction in which the collecting electrodes 20A and 20B extend. Furthermore, the conditions (pressure, the number of vibrations, and amplitude of the ultrasonic vibration tool 14) of the ultrasonic vibration bonding in the first case are the same as those in the second case.

In the first and second cases, the peel forces of the collecting electrodes 20A and 20B were measured in each point on which the ultrasonic vibration bonding has been performed. FIG. 10 illustrates the results of the measurement. In FIG. 10, the vertical axis represents the peel force (can be regarded as peel strength or bonding strength) in gram, whereas the horizontal axis represents the processing points of the collecting electrode 20A (or the collecting electrode 20B) on which the ultrasonic vibration bonding has been performed.

As illustrated in FIG. 10, the peel force in the first case is weak and stable. In other words, even when the ultrasonic vibration bonding is performed to have the weaker peel force, variations in the peel strength (bonding strength) among the processing points are suppressed.

In contrast, as a result of the ultrasonic vibration bonding performed to have the weaker peel force in the second case, variations in the peel strength (bonding strength) among the processing points are wide. For example, even when the ultrasonic vibration bonding is performed by targeting the peel force of 200 g (target value), some of the processing points are not bonded or are subject to the peel force approximately five times as large as the target value. In other words, the collecting electrodes 20A and 20B in the second case commonly have the processing points that are not bonded and damage the solar cell ST1.

As illustrated in FIG. 10, the present invention allows reduction in the variations in the peel strength (bonding strength) among the points even when the collecting electrodes 20A and 20B are bonded onto the glass substrate 1 at a lower peel force.

Furthermore, the Inventors have found the following facts as a result of various experiments. Specifically, the collecting electrodes 20A and 20B are disposed along the sides L1 and L2 of the glass substrate 1, respectively. Then, the glass substrate 1 is pressed along the sides L1 and L2 in the vicinity of the sides L1 and L2 (specifically, in a region of the glass substrate 1 between the side L1 and an arrangement position of the collecting electrode 20A, and in a region of the glass substrate 1 between the side L2 and an arrangement position of the collecting electrode 20B) (see FIGS. 6 and 7). During application of the pressure, the ultrasonic vibration bonding is performed on the collecting electrodes 20A and 20B. Accordingly, the Inventors have found that variations in the peel strength (bonding strength) among the points can be most reduced even when the collecting electrodes 20A and 20B are bonded onto the glass substrate 1 at a lower peel force.

For example, the collecting electrodes 20A and 20B are disposed along the sides L1 and L2 of the glass substrate 1, respectively. Then, the glass substrate 1 is pressed along the sides L1 and L2 in the vicinity of the sides L1 and L2 (specifically, in a region of the glass substrate 1 between the side L1 and an arrangement position of the collecting electrode 20A, and in a region of the glass substrate 1 between the side L2 and an arrangement position of the collecting electrode 20B) (see FIGS. 6 and 7). In addition, the glass substrate 1 is pressed along the sides L3 and L4 in the vicinity of the sides L3 and L4. During application of the pressure (specifically, while all the sides L1 to L4 are pressed), the ultrasonic vibration bonding is performed on the collecting electrodes 20A and 20B. In this case, the Inventors have found that variations in the peel strength (bonding strength) among the points have the same tendency as that of the second case even when the collecting electrodes 20A and 20B are bonded onto the glass substrate 1 at a lower peel force.

Furthermore, the collecting electrodes 20A and 20B are disposed along the sides L1 and L2 of the glass substrate 1, respectively. Then, the glass substrate 1 is pressed along the sides L3 and L4 in the vicinity of the sides L3 and L4. During application of the pressure (specifically, while the sides L3 to L4 are pressed), the ultrasonic vibration bonding is performed on the collecting electrodes 20A and 20B. In this case, the Inventors have found that variations in the peel strength (bonding strength) among the points cannot be reduced as done in the first case, even when the collecting electrodes 20A and 20B are bonded onto the glass substrate 1 at a lower peel force. Furthermore, the collecting electrodes 20A and 20B are disposed along the sides L1 and L2 of the glass substrate 1, respectively. Then, the glass substrate 1 is pressed in places in the vicinity of the sides L1 and L2 (specifically, in a region of the glass substrate 1 between the side L1 and an arrangement position of the collecting electrode 20A, and in a region of the glass substrate 1 between the side L2 and an arrangement position of the collecting electrode 20B). During application of the pressure (specifically, while each point in the vicinity of the sides L1 and L2 is pressed), the ultrasonic vibration bonding is performed on the collecting electrodes 20A and 20B. In this case, the Inventors have found that variations in the peel strength (bonding strength) among the points are wide even when the collecting electrodes 20A and 20B are bonded onto the glass substrate 1 at a lower peel force.

Furthermore, the pressure parts 12A are L-shaped in the cross-sectional view. Furthermore, the substrate fixing parts 12 (pressure parts 12A) can also horizontally move with the drivers 12B. Thus, the glass substrate 1 can be positioned on the table 11 using the pressure parts 12A.

Furthermore, the portions of the pressure parts 12A that abut on the solar cell ST1 are softer than the portions of the pressure parts 12A that abut on the side surfaces of the glass substrate 1. Thus, the pressure parts 12A can be softly pressed to the glass substrate 1, and such pressing can prevent the solar cell ST1 from being damaged. Furthermore, since the portions of the pressure parts 12A that abut on the side surfaces of the glass substrate 1 are not soft, the glass substrate 1 can be positioned with high precision.

The portions of the pressure parts 12A that press the glass substrate 1 may be round.

Furthermore, the controller variably controls the pressure applied by the pressure parts 12A and the conditions of the ultrasonic vibration bonding performed by the ultrasonic vibration tool 14. Thus, the pressure applied by the pressure parts 12A and the conditions of the ultrasonic vibration bonding performed by the ultrasonic vibration tool 14 can be freely changed according to, for example, the thickness and the material of each of the glass substrate 1 and the collecting electrodes 20A and 20B.

Although the present invention is described in detail above, the description does not limit the present invention but exemplifies the present invention in all aspects. It is therefore understood that numerous modifications and variations that have not yet been exemplified can be devised without departing from the scope of the invention.

### DESCRIPTION OF REFERENCE NUMERALS

1 glass substrate, L1 to L4 side, ST1 solar cell, 11 table, 12 substrate fixing part, 12A pressure part, 12B driver, 12C elastic part, 14 ultrasonic vibration tool, 20A and 20B collecting electrode, 25 indentation, 100 electrode bonding apparatus.

1. An electrode bonding apparatus (100) that bonds an electrode (20A, 20B) onto a substrate (1) on which a solar cell (ST1) is formed, along a side (L1, L2) of the substrate, the substrate being rectangular, said electrode bonding apparatus comprising:
a table (11) on which the substrate is mounted;
an ultrasonic vibration tool (14) that performs ultrasonic vibration bonding on the electrode disposed along the side, on the solar cell; and
two pressure parts (12A) that press the substrate, said pressure parts being vertically movable,
wherein the substrate has a first side (L1), and a second side (L2) facing the first side,
one of said pressure parts presses the substrate along the first side, in a first predetermined region of the substrate between the first side and an arrangement position of the electrode, and
the other of said pressure parts presses the substrate along the second side, in a second predetermined region of the substrate between the second side and an arrangement position of the electrode.

2. The electrode bonding apparatus according to claim 1,
wherein said pressure parts are L-shaped in a cross-sectional view, and
said pressure parts are horizontally movable.

3. The electrode bonding apparatus according to claim 2,
wherein a portion of said pressure parts that abuts on the solar cell is softer than a portion of said pressure parts that abuts on a side surface of the substrate.

4. The electrode bonding apparatus according to claim 1, further comprising
a controller that controls said pressure parts,
wherein said controller variably controls pressure applied by said pressure parts.

5. The electrode bonding apparatus according to claim 4,
wherein said controller variably controls a condition of the ultrasonic vibration bonding performed by said ultrasonic vibration tool.

6. An electrode bonding method, comprising:
(A) mounting, on a table (ii), a substrate (1) on which a solar cell (ST1) is formed, the substrate being rectangular;
(B) disposing an electrode (20A, 20B) along a side (L1, L2) of the substrate, on the solar cell:
(C) pressing the substrate along the side, in a region of the substrate between the side and an arrangement position of the electrode; and
(D) bonding the electrode onto the substrate by performing ultrasonic vibration bonding on the substrate during said step (C).
